(19) United States
(12) Patent Application Publication
(10) Pub. No.: US 2025/0301678 A1
(43) Pub. Date: Sep. 25, 2025

(54) SEMICONDUCTOR DEVICE INCLUDING A PLURALITY OF MESAS

(71) Applicant: Infineon Technologies AG, Neubiberg (DE)

(72) Inventors: Mario Salman, München (DE); Thorsten Arnold, Jesenwang (DE); Roman Baburske, Otterfing (DE); Stephan Voß, Sauerlach (DE); Alda Cavallini, München (DE)

(21) Appl. No.: 19/083,633

(22) Filed: Mar. 19, 2025

(30) Foreign Application Priority Data
Mar. 20, 2024 (DE) 102024107919.3

(51) Int. Cl. H10D 12/00; H10D 12/01; H10D 62/10; H10D 62/60

(52) U.S. Cl. CPC H10D 12/481; H10D 12/038; H10D 62/105; H10D 62/127; H10D 62/60

(57) ABSTRACT

A semiconductor device includes trenches extending into a semiconductor substrate from a first surface and patterning the substrate into mesas, including first and second mesas. Each of the first and second mesas includes a first portion of a first conductivity type and a second portion of a second conductivity type. The first portion is arranged between the first surface and the second portion. The first portion of each of the first and second mesas is electrically connected by a contact structure at the first surface. A source region of the second conductivity type included in the first mesa and omitted in the second mesa is electrically connected to the contact structure. At a vertical reference level in the second portion of the first mesa, a doping concentration is by at least a factor of ten higher than at the vertical reference level in the second portion of the second mesa.

### TECHNICAL FIELD

The present disclosure is related to semiconductor devices, in particular to semiconductor devices including a plurality of mesas.

### BACKGROUND

A common requirement of semiconductor devices, e.g. for power electronic applications, is latch-up ruggedness. In fast switching devices such as, for example, insulated gate bipolar transistors (IGBTs), large turn-off dl/dt may lead to high over-voltages causing undesired dynamic avalanche or current filamentation. Improving the latch-up ruggedness of semiconductor devices without negative impact on the electrical behavior, e.g. larger switching losses, is challenging and requires device optimization.

### SUMMARY

An example of the present disclosure relates to a semiconductor device. The semiconductor device includes a plurality of trenches extending into a semiconductor substrate from a first surface. The plurality of trenches patterns the semiconductor substrate into a plurality of mesas comprising a first mesa and a second mesa. Each of the first mesa and the second mesa include a first portion of a first conductivity type and a second portion of a second conductivity type. The first portion is arranged between the first surface and the second portion. The first portion of each of the first mesa and the second mesa is electrically connected by a contact structure at the first surface. The semiconductor device further includes a source region of the second conductivity type. The source region is included in the first mesa and omitted in the second mesa and is electrically connected to the contact structure. At a vertical reference level in the second portion of the first mesa, a doping concentration is by at least a factor of ten higher than at the vertical reference level in the second portion of the second mesa.

Another example of the present disclosure relates to a method of manufacturing a semiconductor device. The method includes forming a plurality of trenches extending into a semiconductor substrate from a first surface. The plurality of trenches patterns the semiconductor substrate into a plurality of mesas comprising a first mesa and a second mesa. Each of the first mesa and the second mesa include a first portion of a first conductivity type and a second portion of a second conductivity type. The first portion is arranged between the first surface and the second portion. The first portion of each of the first mesa and the second mesa is electrically connected by a contact structure at the first surface. The method further includes forming a source region of the second conductivity type. The source region is included in the first mesa and omitted in the second mesa and is electrically connected to the contact structure. At a vertical reference level in the second portion of the first mesa, a doping concentration is set by at least a factor of ten higher than at the vertical reference level in the second portion of the second mesa.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of semiconductor devices and together with the description serve to explain principles of the examples. Further examples are described in the following detailed description and the claims.

FIG. 1A is a cross-sectional view for illustrating a configuration example of a semiconductor device including a first mesa and a second mesa.

FIG. 1B is a schematic graph for illustrating exemplary doping concentration profiles in the first mesa and the second mesa of FIG. 1A.

FIGS. 2 and 3 are cross-sectional views for illustrating configuration examples of semiconductor devices including a first mesa and a second mesa.

FIGS. 4A to 4C illustrate configuration examples of arrangements of a source region in the first mesa.

FIGS. 5 to 8 are cross-sectional views for illustrating configuration examples of semiconductor devices including a first mesa, a second mesa, and third mesas.

FIG. 9 is a cross-sectional view of a configuration example of a semiconductor device based on FIG. 1.

FIG. 10 is a simulated current versus time graph for illustrating the technical benefit of improved latch-up ruggedness of configuration examples described herein.

### DETAILED DESCRIPTION

In the following detailed description, reference is made to the accompanying drawings, which form a part hereof and in which are shown by way of illustrations specific examples of semiconductor devices including a first mesa and a second mesa. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact may be a non-rectifying electrical junction.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a semiconductor device. The semiconductor device may include a plurality of trenches extending into a semiconductor substrate from a first surface. The plurality of trenches may pattern the semiconductor substrate into a plurality of mesas comprising a first mesa and a second mesa. Each of the first mesa and the second mesa may include a first portion of a first conductivity type and a second portion of a second conductivity type. The first portion may be arranged between the first surface and the second portion. The first portion of each of the first mesa and the second mesa may be electrically connected by a contact structure at the first surface. The semiconductor device may further include a source region of the second conductivity type. The source region may be included in the first mesa and omitted in the second mesa and may be electrically connected to the contact structure. At a vertical reference level in the second portion of the first mesa, a doping concentration is by at least a factor of ten higher than at the vertical reference level in the second portion of the second mesa.

The semiconductor device may be part of an integrated circuit or may be a discrete semiconductor device or a semiconductor module, for example. The semiconductor device may be a power semiconductor device may be or may include a vertical power semiconductor device having a load current flow between the first surface and a second surface opposite to the first surface. The power semiconductor device may be or may include a power semiconductor RC-IGBT. The power semiconductor device may be configured to conduct currents of more than 1 A or more than 10 A or even more than 30 A, and may be further configured to block voltages between load terminals, e.g. between collector and emitter or between cathode and anode, in the range of several hundreds of up to several thousands of volts, e.g. 400 V, 650V, 1.2 kV, 1.7 kV, 3.3 kV, 4.5 kV, 5.5 kV, 6 kV, 6.5 kV. The blocking voltage may correspond to a voltage class specified in a datasheet of the power semiconductor device, for example.

The semiconductor substrate may include or consist of a semiconductor material from the group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). For example, the semiconductor substrate may be formed of a base substrate, e.g. wafer, having none, one or even more semiconductor layers such as epitaxial semiconductor layers on the base substrate. The semiconductor substrate may be a Czochralski (CZ), e.g. a magnetic Czochralski, MCZ, or a float zone (FZ), or an epitaxially deposited silicon semiconductor substrate.

The first surface may be a front surface or a top surface of the power semiconductor device, and the second surface may be a back surface or a rear surface of the power semiconductor device, for example. The semiconductor substrate may be attached to a lead frame via the second surface, for example. Over the first surface of the semiconductor substrate, bond pads may be arranged and bond wires may be bonded on the bond pads.

For realizing a desired current carrying capacity, the semiconductor device may be designed by a plurality of parallel-connected device cells, e.g. IGBT cells. The parallel-connected device cells may, for example, be device cells formed in the shape of a stripe or a stripe segment. The device cells can also have any other shape, e.g. circular, elliptical, polygonal such as hexagonal or octahedral. For example, the device cells may be arranged in an active transistor cell area. The active transistor cell area may be defined by an area of the semiconductor substrate where an emitter/source region of IGBT cells at the first surface and a collector region of IGBT cells at the second surface are arranged opposite to one another along the vertical direction. In the active transistor cell area, a load current may enter or exit the semiconductor substrate of the semiconductor device, e.g. via contact plugs on the first surface of the semiconductor substrate. For example, the active transistor cell area may be defined by an area where contact plugs are placed over the first surface for electrically connecting an electrode, e.g. emitter/source electrode, over the first surface to semiconductor layers, e.g. source/emitter regions and/or body regions, in the active transistor cell area.

The semiconductor device may also include an edge termination area that may include a termination structure. Other than the active transistor cell area, the edge termination area is not an area for load current to enter or exit the semiconductor body. In a blocking mode or in a reverse biased mode of the semiconductor device, the blocking voltage between the active transistor cell area and a field-free region laterally drops across the termination structure in the edge termination area. The termination structure may have a higher or a slightly lower voltage blocking capability than the active transistor cell area. The termination structure may include a junction termination extension (JTE) with or without a variation of lateral doping (VLD), one or more laterally separated guard rings, or any combination thereof, for example.

The blocking voltage of the semiconductor device, e.g. power RC-IGBT, may be adjusted along a vertical direction perpendicular to the first surface by adjusting parameters of a drift region, e.g. vertical extent and/or doping profile. An impurity or doping concentration in the drift region may gradually or in steps increase or decrease with increasing distance to the first surface at least in portions of its vertical extension. According to other examples the impurity concentration in the drift region may be approximately uniform in the vertical direction. For semiconductor devices based on silicon, a mean doping concentration in the drift region may be between 5×10¹² cm⁻³ and 1×10¹⁵ cm⁻³, for example in a range from 1×10¹³ cm⁻³ to 2×10¹⁴ cm⁻³. In the case of a semiconductor device based on SiC, a mean doping concentration in the drift region may be between 5×10¹⁴ cm⁻³ and 1×10¹⁷ cm⁻³, for example in a range from 1×10¹⁵ cm⁻³ to 2×10¹⁶ cm⁻³. A vertical extension of the drift region may depend on voltage blocking requirements, e.g. a specified voltage class, of the semiconductor device. When operating the power semiconductor device in voltage blocking mode, a space charge region may vertically extend partly or totally through the drift region depending on the blocking voltage applied to the semiconductor device. When operating the semiconductor device at or close to the specified maximum blocking voltage, the space charge region may reach or penetrate from the drift region into a field stop region. The field stop region is configured to prevent the space charge region from further reaching to the collector at the second surface of the semiconductor substrate.

The first mesa may be a so-called electron mesa for the configuration example of an n-channel device. The higher doping concentration in the first mesa at the vertical reference level compared with the second mesa may serve as a hole barrier keeping holes away from the source/emitter region in the first mesa. For example, the source region may be implanted over an entire length of the first mesa, yielding a low channel loss for electrons, while keeping latch-up ruggedness. The first mesa may have the source region on either one side of the contact structure, or on both sides. The second mesa may be a so-called hole mesa. In view of the lower doping concentration in the second mesa at the vertical reference level compared with the first mesa and in view of the omitted source region in the second mesa, holes do not face a barrier on the way to the contact structure on the first surface that is free of any source region. Thereby, holes in the second mesa flowing to the contact structure at the first surface do not pose a risk for latch-up. The configuration examples described herein allow for an improved latch-up ruggedness. The restriction of hole flow may induce extra plasma confinement. Carrier confinement may be optimized by choosing a proper ratio between hole- and electron-mesas. For example, the second or hole mesas may be arranged with only neighboring so-called source/emitter trenches having trench electrodes connected to source/emitter, only neighboring so called-gate trenches having the trench electrode electrically connected to gate, or both a neighboring gate and neighboring source trench. The first or electron mesas may be formed by only neighboring gate trenches or both a neighboring gate trench and a neighboring source trench. Moreover, an additional benefit of the configuration examples described herein may be a reduction of the turn-on voltage tails since so-called mixed mesas (with neighboring gate and source trench) with an n-source region have an n-doped barrier region.

For example, a first pn junction between the first portion and the second portion in the first mesa may have a smaller vertical distance to the first surface than a second pn junction between the first portion and the second portion in the second mesa. This may allow the first mesa to act as a hole barrier in n-channel devices by a doping concentration profile of an n-barrier region in the second portion of the first mesa having one or more peaks and a decreasing profile toward the first surface of the semiconductor substrate on one side and toward the second surface of the semiconductor substrate on the other side.

For example, a width of the first mesa at the vertical reference level may be larger by 50% to 200% than a width of the second mesa at the vertical reference level. Reducing the width of the second or hole mesa compared to the first or electron mesa may allow for reducing the undesired effect of the second or hole mesa on the carrier confinement in the on-state and at the same time, there is almost the same high conductive path for the turn-off with negative gate off voltages. From a processing point of view, narrow second or hole mesas may be still electrically contacted, e.g. with the same contact groove, as in the first or electron mesa, since no special requirements may be required with respect to a minimum distance towards trench, because no MOS channel region is affected.

For example, the source region may adjoin to only one of opposite sidewalls of the first mesa. In other words, a channel region configured to be controlled in conductivity by field effect (e.g. by applying a voltage to a gate electrode) may be formed on the one of opposite sidewalls of the first mesa but is omitted on the other one of the opposite sidewalls of the first mesa.

For example, the source region may adjoin to both of opposite sidewalls of the first mesa. A channel region configured to be controlled in conductivity by field effect (e.g. by applying a voltage to a gate electrode) may be formed on both of opposite sidewalls of the first mesa.

For example, the first mesa may be laterally confined by a first trench including a gate or source or electrically floating electrode structure and by a second trench including a gate electrode structure.

For example, the second mesa may be laterally confined by a first trench including a gate or source electrode structure and by a second trench including a gate or source or electrically floating electrode structure.

For example, the first mesa may adjoin to a first sidewall of a trench including a gate electrode structure. The second mesa may adjoin to a second sidewall of the trench including the gate electrode structure. The first sidewall is opposite to the second sidewall.

For example, the semiconductor device may further include at least one third mesa laterally arranged between the first mesa and the second mesa. Each of the at least one third mesa may include a first portion of a first conductivity type and a second portion of a second conductivity type. The first portion is arranged between the first surface and the second portion.

For example, the semiconductor device may further include at least one third mesa. The second mesa may be laterally arranged between the first mesa and at least one of the at least one third mesa. Each of the at least one third mesa may include a first portion of a first conductivity type and a second portion of a second conductivity type. The first portion may be arranged between the first surface and the second portion.

For example, at the vertical reference level in the second portion of a mesa of the at least one third mesa, a doping concentration may be by at least a factor of ten higher than at the vertical reference level in the second portion of the second mesa.

For example, the first portion of a mesa of the at least one third mesa may be electrically floating or a source region is omitted in a mesa of the at least one third mesa. In other words, there is no source region in a mesa of the at least one third mesa and/or a mesa of the at least one third mesa is electrically floating.

For example, a width, at the vertical reference level, of at least one of the at least one third mesa may be smaller than a width of the first mesa.

For example, the semiconductor device may be a reverse conducting insulated gate bipolar transistor, RC-IGBT. For example, some power semiconductor devices may require reverse conductivity. During a reverse conducting state, the power semiconductor device conducts a reverse load current. Such devices may be designed such that the forward load current capability (in terms of magnitude) is substantially the same as the reverse load current capability. The RC-IGBT is a typical device that provides for both forward and reverse load current capability. The general configuration of an RC-IGBT is known to the skilled person. Typically, for an RC-IGBT, the forward conducting state is controllable by means of providing a corresponding signal to the gate electrodes, and the reverse conducting state is typically not controllable, but the RC-IGBT assumes the reverse conducting state if a reverse voltage is present at the load terminals due to a corresponding diode area in the RC-IGBT.

For example, at a second vertical reference level in the first portion of the second mesa, a doping concentration may be by at least a factor of ten higher than at the second vertical reference level in the first portion of the first mesa.

For example, the vertical reference level in the second portion of the first mesa may be located in a barrier region of the second conductivity type. A bottom side of the barrier region may have a vertical distance from a bottom side of the trenches of more than 1 μm.

Details with respect to structure, or function, or technical benefit of features described above with respect to a semiconductor device, e.g. a power semiconductor RC-IGBT, likewise apply to the exemplary methods described herein. Processing the semiconductor substrate may comprise one or more optional additional features corresponding to one or more aspects mentioned in connection with the proposed concept or one or more examples described above or below.

An example of the present disclosure relates to a method of manufacturing a semiconductor device. The method may include forming a plurality of trenches extending into a semiconductor substrate from a first surface. The plurality of trenches patterns the semiconductor substrate into a plurality of mesas including a first mesa and a second mesa. Each of the first mesa and the second mesa may include a first portion of a first conductivity type and a second portion of a second conductivity type. The first portion may be arranged between the first surface and the second portion. The first portion of each of the first mesa and the second mesa may be electrically connected by a contact structure at the first surface. The method may further include forming a source region of the second conductivity type. The source region may be included in the first mesa and be omitted in the second mesa and may be electrically connected to the contact structure. At a vertical reference level in the second portion of the first mesa, a doping concentration may be set by at least a factor of ten higher than at the vertical reference level in the second portion of the second mesa.

For example, setting the doping concentration in the second portion of the first mesa may include forming a mask over the first surface. The mask may cover the second mesa. Dopants of the second conductivity type may be introduced into the second portion of the first mesa through an opening in the mask by ion implantation.

For example, a dose of the ion implantation of the dopants of the second conductivity type into the second portion of the first mesa may range from 3×10¹³ cm⁻² to 2×10¹⁴ cm⁻².

For example, introducing dopants of the second conductivity type into the second portion of the first mesa through an opening in the mask by ion implantation may be carried out after ion implantation of dopants of the first conductivity type for forming a body region. A part of the body region that adjoins to a gate structure formed in one of the plurality of trenches may define a channel region. A conductivity in the channel region may be controlled by field-effect via a potential applied to a gate electrode of the gate structure that is electrically isolated from the semiconductor substrate, e.g. from the channel region, by a gate dielectric of the gate structure.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps, or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation, or step may include or may be broken into multiple sub-acts, -functions, -processes, -operations or -steps, respectively. Such sub acts may be included and part of the disclosure of this single act unless explicitly excluded.

The examples and features described above and below may be combined. Functional and structural details (e.g. materials, dimensions) described with respect to the examples above shall likewise apply to the examples illustrated in the figures and described further below.

More details and aspects are mentioned in connection with the examples described above or below. Processing a semiconductor substrate, e.g. a wafer, may comprise one or more optional additional features corresponding to one or more aspects mentioned in connection with the proposed concept or one or more examples described above or below.

The doping level of doped regions illustrated in the figures may be set in relation to one another by adding “+” or “−” to the doping type, e.g. p⁺-doped or p⁻-doped. A p⁺-doped region has a higher doping level than a p-doped region, and a p-doped region has a higher doping level than a p⁻-doped region. The same applies to n-type doping levels.

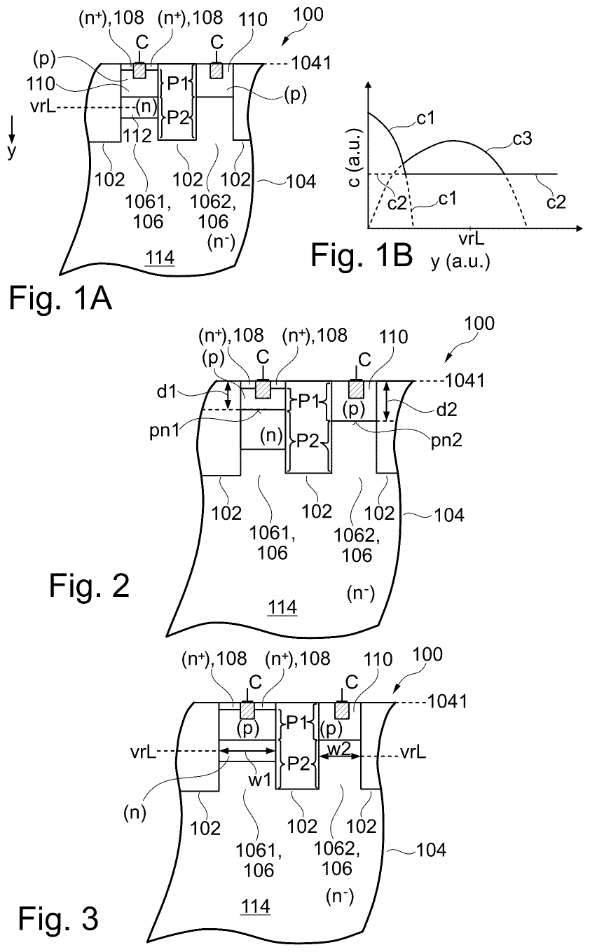

FIG. 1A schematically and exemplarily shows a partial cross-sectional view of an example of a semiconductor device 100.

Multiple trenches 102 extend into a semiconductor substrate 104 from a first surface 1041 of the semiconductor substrate 100. The trenches 102 separate or pattern the semiconductor substrate 104 into a plurality of mesas 106.

The cross-sectional view of FIG. 1A illustrates a first mesa 1061 and a second mesa 1062. The first mesa 1061 and the second mesa 1062 each include a first p-doped portion P1 and a second n-doped portion P2. The first portion P1 is located between the first surface 1041 and the second portion P2. The first portion of each of the first mesa 1061 and the second mesa 1062 is electrically connected by a contact structure C exemplified as a groove contact at the first surface 1041 in FIG. 1A. In some examples related to RC-IGBTs, a p-doped collector region at a rear side of the semiconductor substrate may be replaced by an n-doped region in areas that directly face hole or second mesas 1062, for example (not illustrated in FIG. 1A).

An n⁺-doped source region 108 is formed at the first surface 1041 in the first mesa 1061. The source region 108 adjoins to both of opposite sidewalls of the first mesa 1061. In further configuration examples. The source region 108 may adjoin to only one of opposite sidewalls of the first mesa 1061, for example. The source region 108 is included in the first mesa 1061 and omitted in the second mesa 1062 and is electrically connected to the contact structure C. In each of the first mesa 1061 and the second mesa 1062, a p-doped body region 110 is formed in the first portion P1. The p-doped body region 110 adjoins to both of opposite sidewalls of each of the first mesa 1061 and the second mesa 1062, and is electrically connected to the contact structure C.

At a vertical reference level vRL in the second portion P2 of the first mesa 1061, a doping concentration is by at least a factor of ten higher than at the vertical reference level vRL in the second portion P2 of the second mesa 1062. The doping concentration in the second portion P2 of the first mesa 1061 may define an n-doped barrier region 112.

Exemplary profiles of doping concentration c are illustrated in the schematic graph of FIG. 1B. An intersection of profiles of a doping concentration c1 of the body region 110 and a profile of a doping concentration c2 in a drift region 114 of the second mesa 1062 define a pn junction in the second mesa 1062. Likewise, an intersection of profiles of the doping concentration c1 of the body region 110 and a profile of a doping concentration c3 of the n-doped barrier region 112 in the first mesa 1061 define a pn junction in the first mesa 1061. The single peak profile of doping concentration c3 in the n-doped barrier region 112 is one example out of a vast variety of examples that may define the barrier region 112. For example, box-shaped or multiple peak profiles of doping concentration in the n-doped barrier region 112 may be used, for example.

In the configuration example of a semiconductor device 100 illustrated in FIG. 2, a first pn junction pn1 between the first portion P1, i.e. the p-doped body region 110, and the second portion P2, i.e. the n-doped barrier region 112, in the first mesa 1061 has a smaller vertical distance d1 to the first surface 1041 than a vertical distance d2 from a second pn junction pn2 to the first surface 1041. The second pn junction pn2 is located between the first portion P1, i.e. the p-doped body region 110, and the second portion P2, i.e. the n-doped drift region 114, in the second mesa 1062.

In the configuration example of a semiconductor device 100 illustrated in FIG. 3, a width w1 of the first mesa 1061 at the vertical reference level vRL is larger, e.g. by 50% to 200% than a width w2 of the second mesa 1062 at the vertical reference level vRL.

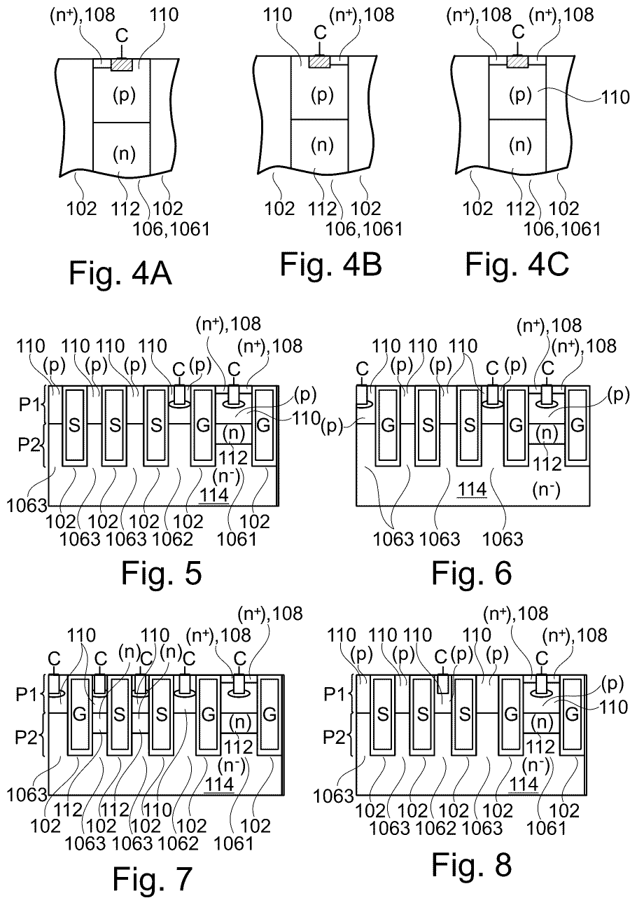

The schematic cross-sectional views of FIGS. 4A to 4C illustrate configuration examples of the first mesa 1061. In the examples illustrated in FIGS. 4A and 4B, source region 108 adjoins to only one of opposite sidewalls of the first mesa 1061. This may result in a one-sided channel region. In the example illustrated in FIG. 4C, the source region 108 adjoins to both of opposite sidewalls of the first mesa 1061.

Referring to the configuration example of a semiconductor device 100 illustrated in FIG. 5, third mesas 1063 are included in the active transistor cell area of the semiconductor device 100. The second mesa 1062 is laterally arranged between the first mesa 1061 and at least one of the third mesas 1063. Each of third mesas 1063 includes, similar to the second mesa 1062, the first portion P1 and the second portion P2. A doping concentration in the second portion of the third mesas 1063 at a vertical reference level of the n-doped barrier region 112 in the first mesa 1061 may be smaller than in the n-doped barrier region 112 in the first mesa 1061. The third mesas 1063 illustrated in FIG. 5 are each electrically floating. This may allow for increasing the current density in another mesa than the electron or first mesa 1061. The source region 108 is omitted in the electrically floating mesa of each of the third mesas 1063. Electrodes in the trenches 102 are either electrically connected to a gate voltage (reference numeral G) or to a source or emitter voltage (reference numeral S).

Although the source region 108 may be omitted in each of the third mesas 1063, the third mesas need not all be electrically floating. Some or even all of the third mesas 1063 may also be electrically connected by the contact structure C as is illustrated in the configuration examples of FIGS. 6 and 7. Moreover, some of the third mesas 1063 may include the n-doped barrier region 112 for increasing the current density away from the electron or first mesa 1061 locally.

As is illustrated in the configuration example of a semiconductor device 100 shown in FIG. 8, one of the third mesas 1063 is laterally arranged between the first mesa 1061 and the second mesa 1062. According to other configuration examples, more than one of the third mesas 1063 may be laterally arranged between the first mesa 1061 and the second mesa 1062.

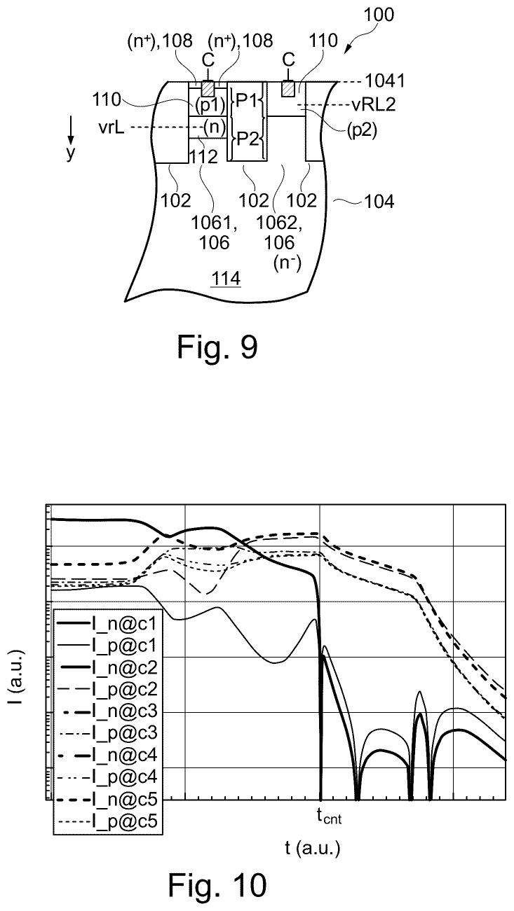

The schematic cross-sectional view of a configuration example of a semiconductor device 100 in FIG. 9 is based on the configuration example of FIG. 1, but differs from the configuration example of FIG. 1 in that, at a second vertical reference level vRL2 in the first portion P1 of the second mesa 1062, a doping concentration p1 is by at least a factor of ten higher than a doping concentration p2 at the second vertical reference level vRL2 in the first portion P1 of the first mesa 1061. This may improve the diode properties of the semiconductor device 100 without affecting the threshold voltage, for example.

The technical benefit of improved latch-up ruggedness is schematically illustrated in the graph of FIG. 10 illustrating simulated current I versus time t during the turn-off dl/dt. Around the critical time range starting with tcrit regarding over-current turn-off ruggedness, the hole peak current I_p@c1 in the electron or first mesa 1061 (see e.g. first mesa 1061 in FIG. 1A) is reduced by orders of magnitude compared with the hole peak current I_p@c2 in the hole or second mesa (see e.g. second mesa 1062 in FIG. 1A), for example.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a plurality of trenches extending into a semiconductor substrate from a first surface, the plurality of trenches patterning the semiconductor substrate into a plurality of mesas comprising a first mesa and a second mesa, wherein each of the first mesa and the second mesa includes a first portion of a first conductivity type and a second portion of a second conductivity type, the first portion being arranged between the first surface and the second portion, and the first portion of each of the first mesa and the second mesa is electrically connected by a contact structure at the first surface; and
a source region of the second conductivity type included in the first mesa and omitted in the second mesa, and being electrically connected to the contact structure,
wherein at a vertical reference level in the second portion of the first mesa, a doping concentration is by at least a factor of ten higher than at the vertical reference level in the second portion of the second mesa.

2. The semiconductor device of claim 1, wherein a first pn junction between the first portion and the second portion in the first mesa has a smaller vertical distance to the first surface than a second pn junction between the first portion and the second portion in the second mesa.

3. The semiconductor device of claim 1, wherein a width of the first mesa at the vertical reference level is larger by 50% to 200% than a width of the second mesa at the vertical reference level.

4. The semiconductor device of claim 1, wherein the source region adjoins to only a single sidewall of the first mesa.

5. The semiconductor device of claim 1, wherein the source region adjoins to both of opposite sidewalls of the first mesa.

6. The semiconductor device of claim 1, wherein the first mesa is laterally confined by a first trench including a gate, source or electrically floating electrode structure, and by a second trench including a gate electrode structure.

7. The semiconductor device of claim 1, wherein the second mesa is laterally confined by a first trench including a gate, source or electrically floating electrode structure, and by a second trench including a gate or source electrode structure.

8. The semiconductor device of claim 1, wherein the first mesa adjoins to a first sidewall of a trench including a gate electrode structure, and the second mesa adjoins to a second sidewall of the trench, the first sidewall being opposite to the second sidewall.

9. The semiconductor device of claim 1, further comprising:
at least one third mesa laterally arranged between the first mesa and the second mesa,
wherein each of the at least one third mesa includes a first portion of the first conductivity type and a second portion of the second conductivity type, the first portion being arranged between the first surface and the second portion.

10. The semiconductor device of claim 1, further comprising:
at least one third mesa,
wherein the second mesa is laterally arranged between the first mesa and at least one of the at least one third mesa,
wherein each of the at least one third mesa includes a first portion of the first conductivity type and a second portion of the second conductivity type, the first portion being arranged between the first surface and the second portion.

11. The semiconductor device of claim 10, wherein at the vertical reference level in the second portion of a mesa of the at least one third mesa, a doping concentration is by at least a factor of ten higher than at the vertical reference level in the second portion of the second mesa.

12. The semiconductor device of claim 10, wherein the first portion of a mesa of the at least one third mesa is electrically floating or a source region is omitted in a mesa of the at least one third mesa.

13. The semiconductor device of claim 10, wherein at the vertical reference level, a width of at least one of the at least one third mesa is smaller than a width of the first mesa.

14. The semiconductor device of claim 1, wherein the semiconductor device is a reverse conducting insulated gate bipolar transistor.

15. The semiconductor device of claim 1, wherein at a second vertical reference level in the first portion of the second mesa, a doping concentration is by at least a factor of ten higher than at the second vertical reference level in the first portion of the first mesa.

16. The semiconductor device of claim 1, wherein the vertical reference level in the second portion of the first mesa is located in a barrier region of the second conductivity type, and a bottom side of the barrier region has a vertical distance from a bottom side of the trenches of more than 1 μm.

17. The semiconductor device of claim 1, wherein the first mesa and the second mesa form a device cell, and wherein a plurality of equally formed device cells spans across an entire active transistor cell area of the semiconductor device.

18. A method of manufacturing a semiconductor device, the method comprising:
forming a plurality of trenches extending into a semiconductor substrate from a first surface, the plurality of trenches patterning the semiconductor substrate into a plurality of mesas comprising a first mesa and a second mesa, wherein each of the first mesa and the second mesa includes a first portion of a first conductivity type and a second portion of a second conductivity type, the first portion being arranged between the first surface and the second portion, and the first portion of each of the first mesa and the second mesa is electrically connected by a contact structure at the first surface;
forming a source region of the second conductivity type in the first mesa and omitted in the second mesa, and being electrically connected to the contact structure; and
at a vertical reference level in the second portion of the first mesa, setting a doping concentration by at least a factor of ten higher than at the vertical reference level in the second portion of the second mesa.

19. The method of claim 18, wherein setting the doping concentration in the second portion of the first mesa comprises:
forming a mask over the first surface that covers the second mesa; and
introducing dopants of the second conductivity type into the second portion of the first mesa through an opening in the mask by ion implantation.

20. The method of claim 19, wherein a dose of the ion implantation ranges from 3×10¹³ cm⁻² to 2×10¹⁴ cm⁻².

21. The method of claim 19, wherein introducing dopants of the second conductivity type into the second portion of the first mesa through an opening in the mask by ion implantation is carried out after ion implantation of dopants of the first conductivity type for forming a body region.
